(19) United States
(12) Patent Application Publication
(10) Pub. No.: US 2018/0234595 A1
(43) Pub. Date: Aug. 16, 2018

(54) Camera Module

(71) Applicant: Google Inc., Mountain View, CA (US)

(72) Inventors: David Kyungtag Lim, Glenview, IL (US); Jason Edward Jordan, Burlingame, CA (US); Paul Lynn Fordham, Wauconda, IL (US)

(21) Appl. No.: 15/429,249

(22) Filed: Feb. 10, 2017

(51) Int. Cl. H04N 5/225; H05K 1/18

(52) U.S. Cl. CPC H04N 5/2252; H04N 5/2254; H05K 2201/10151; H05K 1/183; H05K 2201/10121; H04N 5/2258

(57) ABSTRACT

An electronic device including a camera module is provided. In some embodiments, the camera module includes a circuit board having a front face and a rear face, an image sensor having a front face and a rear face, the image sensor electrically connected to the circuit board, and first and second optical elements arranged in front of the front faces of the image sensor and the circuit board. The front face of the circuit board and the front face of the image sensor are each attached to the first optical element.

### BACKGROUND

Camera modules that can be included in an electronic device are well known. Many electronic devices, such as mobile phones and digital cameras, include one or more camera modules configured to capture images and video. Such camera modules often include a housing or frame, a plurality of lenses, a circuit board, and an image sensor mounted with the circuit board. The camera module is often housed within an electronic device and electrically connected to other components of the electronic device. Various configurations of camera modules designed to fit within a small space in the electronic device have been proposed.

### SUMMARY

In general, this document describes devices, systems, and methods related to camera modules in electronic devices. Some electronic devices may include an image sensor having a front face, a circuit board electrically connected with the image sensor and having a front face, and a first lens attached to both the image sensor and the circuit board. The first lens may be directly attached to the front faces of each of the image sensor and the circuit board to provide mechanical support for the image sensor. The first lens may provide both an optical function as light passes through the first lens to the image sensor, and structurally support the image sensor. Such configurations can provide space savings by efficiently supporting the image sensor at least partially with the first lens such that other structural components may have smaller dimensions or may be removed from the camera module altogether. Electronic devices including some camera modules described herein may thus have a smaller overall size and/or accommodate additional components or larger components.

As additional description to the embodiments described below, the present disclosure describes the following embodiments.

Embodiment 1 is a camera module, comprising: a circuit board having a front face and a rear face; an image sensor having a front face and a rear face, the image sensor electrically connected to the circuit board; and a first optical element arranged in front of the front face of the image sensor and the front face of the circuit board, wherein the front face of the circuit board and the front face of the image sensor are each directly attached to the first optical element.

Embodiment 2 is the camera module of embodiment 1, wherein the image sensor is nested in an opening of the circuit board.

Embodiment 3 is the camera module of any of the preceding embodiments, wherein an entire perimeter of the image sensor is surrounded by the circuit board.

Embodiment 4 is the camera module of any of the preceding embodiments, wherein the image sensor is electrically connected to the circuit board by wire leads extending between the image sensor and the circuit board.

Embodiment 5 is the camera module of any of the preceding embodiments, wherein the image sensor is attached to the first optical element over the entire front face of the image sensor.

Embodiment 6 is the camera module of any of the preceding embodiments, wherein the first optical element has a concave shape and the image sensor is attached to the first optical element around a perimeter of the concave shape.

Embodiment 7 is the camera module of any of the preceding embodiments, wherein the first optical element includes a central lens portion made from a first material and a surrounding frame portion made from a second material.

Embodiment 8 is the camera module of any of the preceding embodiments, wherein the front face of the circuit board is attached to the surrounding frame portion and the front face of the image sensor is attached to the central lens portion.

Embodiment 9 is the camera module of any of the preceding embodiments, further comprising an electronic device having a front cover and a display visible through the front cover.

Embodiment 10 is the camera module of any of the preceding embodiments, wherein the image sensor is arranged to receive light through an aperture of the front cover.

Embodiment 11 is the camera module of any of the preceding embodiments, further comprising an electronic device housing including a rear surface opposite the front cover, wherein the image sensor is arranged to receive light through the rear surface of the electronic device housing.

Embodiment 12 is the camera module of any of the preceding embodiments, further comprising third and fourth optical elements, the second, third and fourth optical elements arranged in a lens barrel.

Embodiment 13 is the camera module of any of the preceding embodiments, further comprising a voice coil motor, at least one of the second, third, or fourth optical elements movable by the voice coil motor.

Embodiment 14 is an electronic device, comprising: a circuit board having a front face and a rear face; an image sensor having a front face and a rear face, the image sensor nested in an opening of the circuit board and electrically connected to the circuit board; a first and optical element arranged in front of the front faces of the image sensor and the circuit board; a user interface display; and a housing having an aperture, wherein the front face of the circuit board and the front face of the image sensor are attached to the first optical element, the image sensor arranged in alignment with the aperture of the housing.

Embodiment 15 is the camera module of embodiment 14, wherein the image sensor is directly attached to the first optical element over the entire front face of the image sensor.

Embodiment 16 is the camera module of any of embodiments 14-15, wherein the first optical element includes a central lens portion made from a first material and a surrounding frame portion made from a second material.

Embodiment 17 is the camera module of any of any of embodiments 14-16, further comprising third and fourth optical elements, the second, third and fourth optical elements arranged in a lens barrel.

Embodiment 18 is the camera module of any of embodiments 14-17, further comprising a voice coil motor, at least one of the second, third, or fourth optical elements movable by the voice coil motor relative to the first optical element and the image sensor.

Embodiment 19 is a method of manufacturing a camera module, comprising: electrically connecting an image sensor with a circuit board; attaching a first optical element directly to a front face of an image sensor and a front face of the circuit board; enclosing the circuit board, image sensor, and first optical element within a housing of an electronic device.

Embodiment 20 is the method of embodiment 19, wherein the step of attaching a first optical element comprises directly attaching the first optical element to the entire front face of the image sensor.

These and other embodiments of the disclosed technology described herein may provide one or more of the following benefits. First, some configurations described herein enable smaller electronic devices. A camera module having an image sensor at least partially supported by attachment to a lens can allow one or more other structural components of the camera module to be eliminated or reduced in size. The camera module may thus occupy less space within an electronic device.

Second, some configurations described herein can allow for varied arrangement and/or assembly of other components within the electronic device. For example, a camera module having a smaller size (e.g., a reduced height) can facilitate assembly of larger or additional components within the electronic device.

Third, some configurations described herein can enable improved image quality of images and video captured by the camera module. By reducing the size of, or eliminating, one or more other structural elements for supporting the image sensor, the camera module or electronic device can accommodate larger or additional optical elements that can improve image quality without requiring increased overall size of the camera module or electronic device.

The details of one or more embodiments are set forth in the accompanying drawings and the description below. Other features and advantages will be apparent from the description and drawings, and from the claims.

### DESCRIPTION OF THE DRAWINGS

The details of one or more embodiments are set forth in the accompanying drawings and the description below, and wherein:

FIG. 1 is a perspective exploded view of an example electronic device having a camera module.

FIG. 2 is a cross-sectional, perspective view of an example camera module.

FIG. 3 is partial top view of the camera module of FIG. 2.

FIG. 4 is a partial top view of an example camera module.

FIG. 5 is a cross-sectional, perspective view of an example camera module.

FIG. 6 is a cross-sectional, perspective view of an example camera module.

FIG. 7 is a flow diagram of an example method of manufacturing a camera module.

### DETAILED DESCRIPTION OF ILLUSTRATIVE EMBODIMENTS

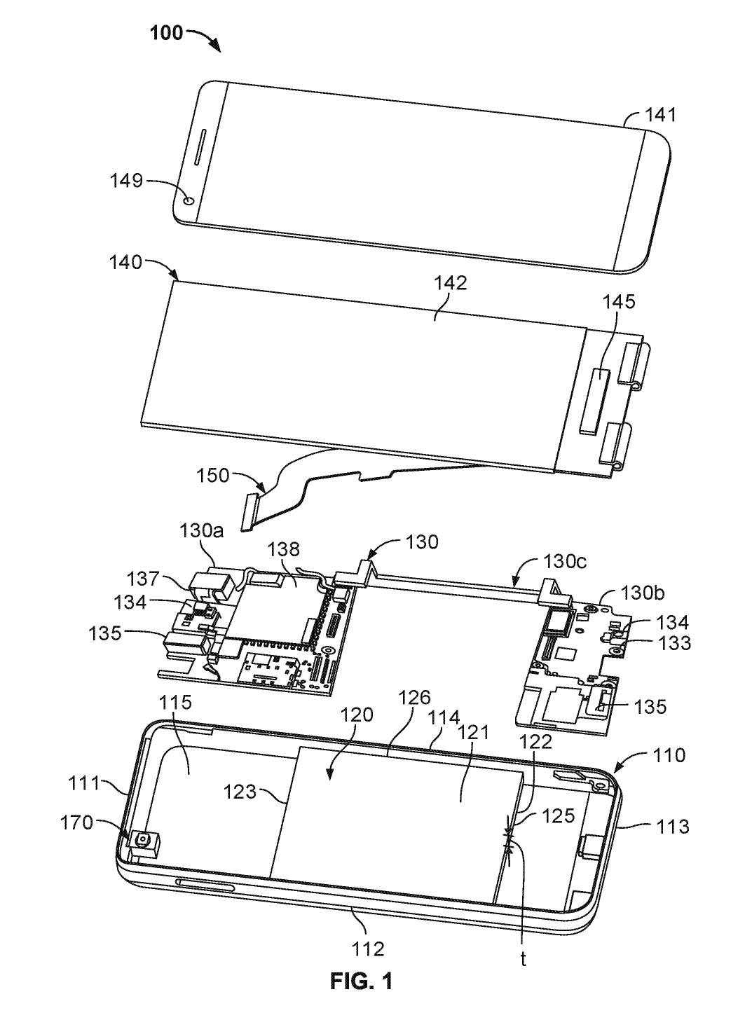

Referring to FIG. 1, an example electronic device 100 is shown, including an electronic device housing 110, battery 120, circuit board 130, display assembly 140, and camera module 170. Camera module 170 is configured to capture high-quality images and video while occupying a relatively small volume within electronic device housing 110. In some embodiments, camera module 170 includes an image sensor supported by an optical element that functions to transmit light to an image sensor.

Electronic device 100 may be an electronic device including a camera module, such as a mobile phone, music player, tablet, laptop computing device, wearable electronic device, data storage device, display device, adapter device, desktop computer, digital camera, or other electronic device.

Electronic device housing 110 may be a bucket-type enclosure having first, second, third, and fourth side portions 111, 112, 113, 114 that define outer sidewalls of electronic device 100, and a back major planar face 115 integrally formed with side portions 111, 112, 113, 114. A bucket-type enclosure allows components of electronic device 100 to be accommodated within housing 110 and enclosed by an outer cover, such as outer cover 141. In other embodiments, one or more side portions 111, 112, 113, 114, and/or back major planar face 115 may be formed separately and subsequently joined together (e.g., with one or more adhesives, welds, snap-fit connectors, fasteners, etc.) to form electronic device housing 110. In various embodiments, electronic device housing 110 may be an H-beam type housing or other electronic device housing 110 that includes one or more walls that provide a housing to at least partially support and/or enclose components of electronic device 100.

Electronic device housing 110 is made from a material that provides adequate structural rigidity to support and protect internal components of electronic device 100. In some embodiments, electronic device housing 110 is formed from a single piece of metal. Electronic device housing 110 may be milled, molded, forged, etched, printed, or otherwise formed. Alternatively or additionally, electronic device housing 110 may be formed from plastic, glass, wood, carbon fiber, ceramic, combinations thereof, and/or other materials.

Electronic device housing 110 and an outer cover 141 define an interior volume that can house various components of electronic device 110, including battery 120, circuit board 130, display assembly 140, and camera module 170. Electronic device housing 110 can accommodate additional components of electronic device 100, such as microphone 133, speaker 134, sensors 135, such as fingerprint sensors, proximity sensors, accelerometers, and/or other sensors, flash devices 137, processor 138, antennas, and/or other components. In various embodiments, some or all of these components may be electrically connected with circuit board 130.

Display assembly 140 provides a user interface display that displays information to a user. For example, display assembly 140 may provide a touch screen display that a user can interact with to view displayed information and to provide input to electronic device 100. In some embodiments, display assembly 140 occupies substantially all or the majority of a front major face 116 of electronic device 100 (e.g., and covers battery 120 and first, second, and third circuit boards 130a, 130b, 130c), and includes a rectangular visible display.

Display assembly 140 includes one or more substrate layers that provide the visible display and/or allow display assembly 140 to receive touch input from a user. For example, outer cover 141 may serve as an outermost layer that encloses other components of display assembly 140 and electronic device 100 and that a user may physically touch to provide input to electronic device 100. In some embodiments, display assembly 140 includes a liquid crystal display (LCD) panel 142 including a liquid crystal material positioned between one or more color filter and thin-film-transistor (TFT) layers. The layers of display panel 142 may include substrates formed from glass or polymer, such as polyamide. In various embodiments, display assembly 140 may be a light-emitting diode (LED) display, an organic light-emitting diode (OLED) display, such as an active-matrix organic light-emitting diode (AMOLED) display, a plasma display, an electronic ink display, or other display that provides visual output to a user.

Display assembly 140 includes driver circuitry used to control display output and/or receive user input. In some embodiments, driver circuitry includes a display integrated circuit 145 that is mounted in electrical communication with the TFT layers of display panel 142, for example by gate lines or other electrical connection. Display integrated circuit 145 may receive display data from processor 138, for example, and deliver corresponding signals to control the optical properties of a liquid crystal layer, for example, to produce a visible output.

Connection between display integrated circuit 145 and circuit board 130 (and processor 138, for example) may be provided by an electrical conductor that facilitates a robust electrical connection while maintaining a low profile configuration that does not significantly increase the overall dimensions of electronic device 100. In some embodiments, a flex conductor 150 connects display integrated circuit 145 and circuit board 130. Flex conductor 150 includes conductive structures on a thin, flexible substrate. Flex conductor 150 has a relatively thin profile and may be bent along a longitudinal direction to fit between various components of electronic device 100, such as to connect from a front face of a display substrate to circuit board 130 by passing between battery 120 and a rear of display assembly 140. Flex conductor 150 may be connected between first circuit board 130a (e.g., a top circuit board) or second circuit board 130b (e.g., a bottom circuit board). Alternatively or additionally, further electrical communication between display assembly 140 and the other of first circuit board 130a or second circuit board 130b is provided via third circuit board 130c.

Components of display assembly 140 and flex conductor 150 may be positioned within electronic device 100 such that the space required to connect display assembly 140 with circuit board 130 is reduced. In some embodiments, display integrated circuit 145 may be positioned at a bottom of display substrate 142 (e.g., a portion of display substrate 142 close to bottom wall 113) and flex conductor 150 wraps around a back side of display substrate 142 to connect with first and/or second circuit boards 130a, 130b. In some embodiments, display integrated circuit 145 may be positioned at a top of display substrate 142 (e.g., a portion of display substrate 142 close to top wall 111) and flex conductor 150 wraps around a back side of display substrate 142 to connect with first and/or second circuit boards 130a, 130b. In some embodiments, display integrated circuit 145 may be positioned along a side of display substrate 142 (e.g., a side portion of display substrate 142 close to sidewall 112 or sidewall 114) and flex conductor wraps around a back side of display substrate 142 to connect with first and/or second circuit boards 1301, 130b. In some embodiments, display integrated circuit 145 and flex conductor 150 are positioned so that flex conductor 150 does not extend between display assembly 140 and battery 120. Positioning the battery 120 directly adjacent display assembly 140 (e.g., without an intervening electrical conductor 150 passing between battery 120 and display assembly 140) facilitates an increased battery size having a greater power capacity.

Conductive structures of flex conductor 150 may include conductive lines, printed conductive traces, or other conductive components that provide electrical connection between respective electrical contacts associated with display integrated circuit 145 and circuit board 130. Flex conductor 150 may be a single, double, or multi-layer flexible printed circuit including a polyamide, PEEK, polyester, having printed or laminated conductive elements, for example. Such construction provides robust electrical characteristics that can provide reliable connection between various components while having a low bending radius to facilitate compact arrangement of flex conductor 150 within electronic device 100.

Battery 120 is positioned within electronic device housing 110. In some embodiments, battery 120 is positioned substantially centrally and/or towards a bottom region of electronic device housing 110 that may promote a user's perception of stability when electronic device 100 is handled. For example, battery 120 may be positioned adjacent to first, second, and/or third circuit boards 130a, 130b, 130c such that battery 120 is positioned substantially centrally between top and bottom sidewalls 111, 113. In other embodiments, battery 120 may be positioned in a stacked configuration such that circuit boards 130a and/or 130b are between battery 120 and display assembly 140 (e.g., sandwiched between battery 120 and display assembly 140), or vice versa.

Battery 120 provides a primary source of power for electronic device 100 and its components. Battery 120 may include a secondary cell, rechargeable battery configured for use through thousands of battery charging cycles over the entire useful life of electronic device 100, for example. In various embodiments, battery 120 may be a lithium polymer battery, lithium ion battery, nickel metal hydride battery, nickel cadmium battery, or other battery type configured to power electronic device 100 over many charging cycles. Alternatively or additionally, battery 120 may include a primary cell battery configured to be replaced when substantially discharged.

Battery 120 is shaped to provide a desired power capacity in a space-efficient configuration. In some embodiments, battery 120 has front and back major planar faces 121, 122 separated by minor sides 123, 124, 125, 126 defining a thickness (t_{thickness}) of battery 120. For example, sides 123, 125, may be parallel with top and bottom sidewalls 111, 113 of electronic device housing 110, and extend substantially across a width of electronic device housing 110, such as more than 50%, more than 75%, or more than 90% of the width of electronic device housing. Such a configuration promotes a relatively high power capacity for a battery having a particular power density.

Circuit board 130 is configured to accommodate components of electronic device 100 in a space-efficient manner, and provide robust mechanical and electrical connections between these components. Circuit board 130 may support and/or electrically connect one or more components of electronic device 100 such as one or more of battery 120, display 140, camera module 170, microphone 133, speaker 134, sensors 135, flash devices 137, processor 138, electrical connectors (e.g., USB connectors, audio connectors, etc.), antenna lines, and/or other components. In some embodiments, circuit board 130 includes first circuit board 130a positioned at a top region of electronic device housing 110, second circuit board 130b positioned at a bottom region of electronic device housing 110. Third circuit board 130c connects the first and second circuit boards 130a, 130b. First, second, and third, circuit boards 130a, 130b may be separately formed circuit boards and may be electrically connected by an electrical conductor. In other embodiments, first and second circuit boards 130a, 130b are integrally formed as a unitary circuit board with third circuit board 130c extending between first and second circuit boards 130a, 130b. First, second, and/or third circuit boards 130a, 130b, 130c may be printed circuit boards, flexible circuit boards, other circuit board types, and/or combinations thereof.

First and second circuit boards 130a, 130b may be positioned at top and bottom positions of electronic device housing 110 so that various components may be accommodated at top and bottom regions of the electronic device. For example, first circuit board 130a is positioned at a top region of electronic device housing 110 and may include components beneficially positioned at the top region. First circuit board 130a may accommodate components such as camera module 170, an earpiece assembly including a speaker, proximity sensor, antenna lines, a microphone configured to receive audio from the external environment that may be processed to provide noise cancellation, camera flash, diversity antenna, and/or other components. Second circuit board 130 is positioned at a bottom region of electronic device housing 110 and may include components beneficially positioned at the bottom region. Second circuit board may accommodate components such as an electrical connector (e.g., USB connectors, audio connectors, etc.), audio speaker, microphone to receive audio input from a user or the external environment, vibrator, and/or other components. Such positioning may promote functionality and usability of the components by a user of electronic device 100.

Third circuit board 130c may accommodate one or more other electrical components and/or electrically connect various components of first and second boards 130a, 130b. In some embodiments, third circuit board 130c includes one or more of a hall effects sensor, battery thermistor, magnetometer, or other electronic components. Third circuit board 130c may electrically connect processor 138, on first circuit board 130a, for example, with the components of second circuit board 130b. In some embodiments, circuit board 130c provides the only electrical connection between first and second circuit boards 130a, 130b. Electronic device 100 may not include a flex conductor, for example, extending over battery 120 between first and second circuit boards 130a, 130b, and may not include a flex conductor extending over battery 120 (e.g., between battery 120 and display assembly 140) at all.

Camera module 170 is mounted within electronic device housing 110 and configured to capture images and video. Camera module 170 may be aligned with one or more openings or transparent apertures 149 that allow transmission of light to camera module 170. For example, camera module 170 may be a front facing camera module 170 aligned with aperture 149 through front cover 141. Alternatively or additionally, electronic device 100 may include a rear facing camera module 170 aligned with an aperture through electronic device housing 110 (e.g., through back major planar face 115).

Camera module 170 is electrically connected with first, second, and/or third circuit boards 130a, 130b, 130c, including processor 138, such that control signals may be transmitted to camera module 170, and data captured by camera module 170 may be transmitted to processor 138 or other electronic components of electronic device 100. In some embodiments, camera module may be mounted directly to electronic device housing 110 and electrically connected with circuit board 130, such as first circuit board 130a positioned at a top region of electronic device housing. In other embodiments, camera module 170 may be mounted on circuit board 130 and assembled within electronic device housing 110 with circuit board 130.

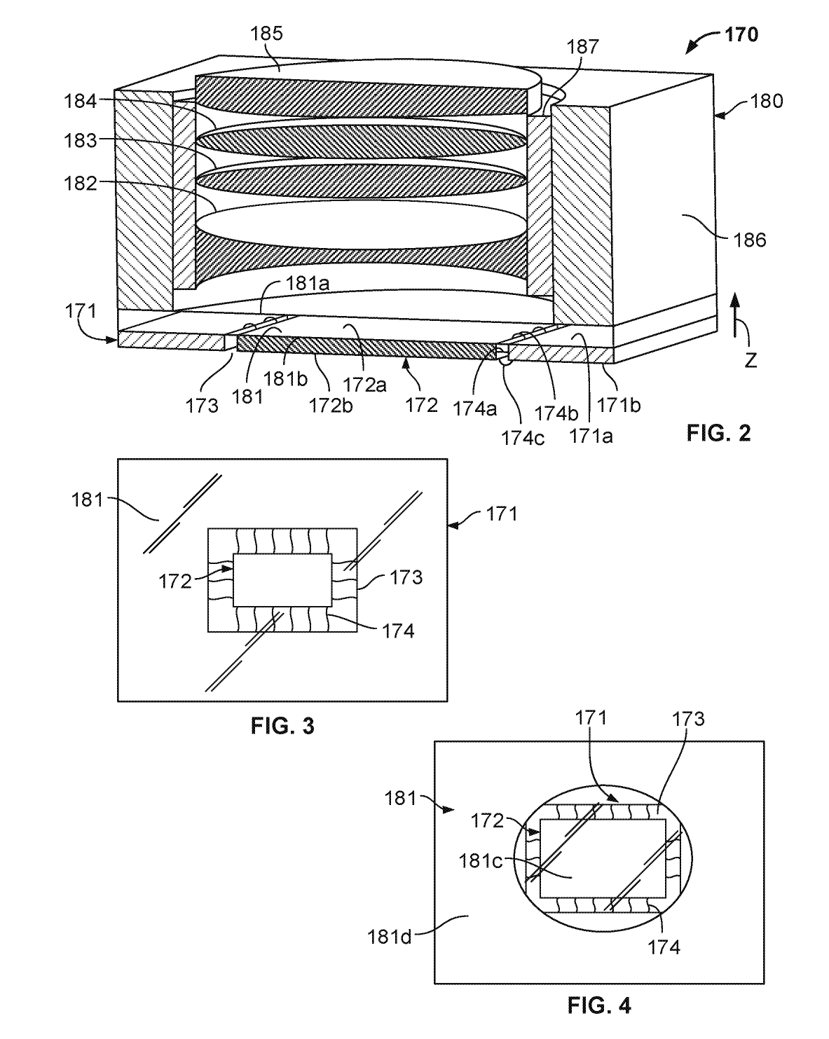

Referring to FIG. 2, a cross-sectional, perspective view of camera module 170 is shown. Camera module 170 includes a circuit board 171, image sensor 172, and lens assembly 180. Lens assembly 180 includes a first optical element 181 and one or more outer optical elements, such as second optical element 182, third optical element 183, and fourth optical element 184. Image sensor 172 captures light focused through lens assembly 180, and communicates associated image data to circuit board 171. In various embodiments, image sensor 172 may include a charged coupled device (CCD) image sensor, complementary metal-oxide-semiconductor (CMOS) image sensor, active pixel sensor (APS) image sensor, N-type metal-oxide-semiconductor (NMOS), combinations thereof, and/or other sensors.

Circuit board 171 may be integrally formed with circuit board 130 (e.g., circuit board 171 is a portion of circuit board 130). In other embodiments, circuit board 171 may be a circuit board primarily dedicated to camera module 170 that is formed separately from circuit board 130 and subsequently electrically connected with circuit board 130 during manufacture of electronic device 100. In various embodiments, circuit board 171 may be a printed circuit board, flexible circuit, other circuit board type, and/or combinations thereof.

Camera module 170 may be configured to provide a space-efficient module that can fit in a relatively small space within electronic device 100. Camera module 170 may be configured to have a reduced thickness, such as a reduced thickness along the z-axis in a direction that image sensor receives light through aperture 149. In some embodiments, circuit board 171 and image sensor 172 are arranged at least partially laterally to one another such that thicknesses of circuit board 171 and image sensor 172 do not each independently add to the overall thickness of camera module 172. For example, circuit board 171 includes a cut-out through the entire thickness of circuit board 171 that defines a space 173 in which image sensor 172 is accommodated. In other embodiments, circuit board 171 may include a region of reduced thickness in which image sensor 172 is accommodated, and/or may include a carrier layer mounted below circuit board 171 and image sensor 172.

Image sensor 172 includes a front face 172a aligned with optical elements of lens assembly 180. In some embodiments, front face 172a of image sensor 172 is directly attached to a rear face 181b of first optical element 181 (e.g., no intervening substrates are present between front face 172a and rear face 181b). First optical element 181 is at least partially transparent such that light may pass through a thickness of first optical element 181 to reach image sensor 172, while also providing structural support for image sensor 172 attached to first optical element 181. In some embodiments, front face 172a of image sensor 172 is directly bonded to first optical element 181 by an adhesive, such as an optically transparent adhesive, welds, or otherwise attached while allowing light to be transmitted to image sensor 172 without excessive distortion.

Front face 171a of circuit board 171 is attached to rear face 181b of first optical element 181. In some embodiments, front face 171a of circuit board 171 is directly bonded to the rear face of first optical element 181 by an adhesive, welds, or otherwise attached to provide a robust structural connection between circuit board 171 and first optical element 181. Front face 171a of circuit board 171 and front face 172a of image sensor 172 are thus each mechanically attached to a common optical element (e.g., a rear face of first optical element 181). Image sensor 172 is supported via attachment on front face 172a, which can eliminate, or reduce the thickness of, one or more support components attached to a rear face of circuit board 171 and/or image sensor 172. Further, first optical element 181 simultaneously provides optical benefits while providing structural support to image sensor 172. In this way, image sensor 172 is supported by camera module 170 in a compact configuration having a reduced thickness (e.g., compared to some configurations having an additional structural support attached to a rear of image sensor 172).

Front faces 171a, 172a of circuit board 171 and image sensor 172, respectively, may be fixed relative to one another in a coplanar relationship. For example, front face 171a and front face 172a may each be attached to a common surface of first optical element 181 that is at least partially planar along the rear face 181a. Rear face 181b of first optical element 181 may be substantially planar such that front faces 171a, 172a are likewise coplanar when attached to rear face 181b. In some embodiments, rear face 181b is substantially planar over the entire rear face 181b, and front face 172a of image sensor 172 is similarly substantially planar over the entire face such that front face 172a of image sensor 172 is directly attached to rear face 181b over substantially the entire area of front face 172a.

In other embodiments, optical element 181 may have a concave, convex, aspheric, or otherwise non-planar profile in front of at least a portion of image sensor 172. One or more portions of rear face 181b may be directly attached with front face 172a and one or more portions of rear face 181b may be separated from front face 172a by a gap. For example, rear face 181b of optical element 181 may have a concave surface such that a gap is present between front face 172a of image sensor 172 and rear face 181b of optical element 181. Rear face 181b may be attached with front face 172a around a perimeter of the concave region of rear face 181b. Alternatively or additionally, front face 181a may include a non-planar surface.

Front face 171a of circuit board 171 is likewise at least partially attached to rear face 181b of first optical element 181. Rear face 181b may be directly attached to front face 171a of circuit board 171 over substantially the entire area of front face 171a. In other embodiments, such as embodiments in which rear face 181b has a non-planar profile, one or more portions of rear face 181b may be directly attached with front face 171a while other portions are separated from front face 171a by a gap.

Lens assembly 180 may include a plurality of optical elements having optical characteristics that facilitate capture of high-quality images by image sensor 172. Lens assembly 180 includes one or more optical elements housed within barrel 187, such as second, third, fourth, and fifth optical elements 182, 183, 184, 185. One or more of optical elements 182, 183, 184, 185 may be shaped to provide a desired optical power. For example, optical elements 182, 183, 184, 185 may have surfaces that are planar, concave, convex, and/or aspheric in shape. In some embodiments, optical elements 182, 183, 184, 185 each have surfaces that differ in shape. Alternatively or additionally, optical elements 182, 183, 184, 185 may have same thickness. One or more of optical elements 181, 182, 183, 184, 185 may be a filtering element, such as an infrared cutoff filter. Alternatively or additionally, one or more optical elements 181, 182, 183, 184, 185 may include an infrared filter coating or layer.

Lens barrel 187 and/or one or more optical elements 182, 183, 184, 185 may be movable relative to image sensor 172 and first optical element 181 along an optical path to adjust the optical focus of an object onto image sensor 172. For example, lens assembly may include a micro-electro-mechanical system (MEMS) actuator configured to move one or more lenses of lens assembly 180 along an optical axis (e.g., closer or further from front face 172a of image sensor 172). In other embodiments, camera module 170 may include a voice coil motor (VCM), a piezo actuator, other actuators, and/or combinations thereof, to move one or more optical elements relative to image sensor 172 and first optical element 181. Second, third, fourth, and/or fifth optical elements 182, 183, 184, 185 may thus move relative to circuit board 171 and image sensor 172 while first optical element 181 is maintained in a fixed relationship with circuit board 171 and image sensor 172.

Lens barrel 187 and second, third, fourth, and fifth optical elements 182, 183, 184, 185 are mounted in front of first optical element 181 and image sensor 172. For example, lens barrel 187 may be mounted to front face 181a of first optical element 181. Lens barrel 187 may be directly mounted to first optical element 181 or indirectly mounted via one or more components, such as camera module frame 186 attached to first optical element 181. In some embodiments, circuit board 171, image sensor 172, and frame 186 (e.g., that one or more of second, third, fourth, fifth optical elements 182, 183, 184, 185 move within) are each directly attached to first optical element 181.

Referring to FIG. 3, a partial top view of camera module 170 is shown, including first optical element 181 in front of circuit board 171 and image sensor 172. Image sensor 172 is nested within space 173, and an entire perimeter of image sensor 172 is surrounded by circuit board 171. Electrical connections 174 electrically connect circuit board 171 with image sensor 171. Electrical connections 174 allow electrical communication between circuit board 171 and image sensor 172, such as to transmit control signals and data captured by image sensor 172. Electrical connections 174 may include wire bonds or other electrical connections that facilitate transmission of control signals and data.

In some embodiments, electrical connections 174 include lateral wire bonds between adjacent sides of circuit board 171 and image sensor 172. For example, electrical connections 174 may be positioned to the rear of front faces 171a, 171b, such that electrical connections 174 are entirely to the rear of rear face 181b of first optical element 181 (e.g., such as electrical connections 174a in FIG. 2). Such a configuration may facilitate a compact arrangement having a relatively reduced thickness by accommodating electrical connections 174 within space 173 between circuit board 171 and image sensor 172. Alternatively or additionally, electrical connections 174 may extend above front face 171a of circuit board 171 and/or front face 172a of image sensor 172. For example, electrical connections 174b extend in front of front faces 171a, 172a. First optical element 181 may include a space or gap to accommodate portions of electrical connections 174b that extend to the front of rear face 181b (e.g., in front of portions of rear face 181b that are directly attached with front face 171a and/or front face 172a. Likewise, electrical connections 174 may alternatively or additionally extend to the rear of rear face 171b of circuit board 171 and/or rear face 172b of image sensor 172. For example, electrical connections 174c extend to the rear of rear faces 171b, 172b. Electronic device 100 includes clearance to the rear of rear faces 171b, 172b to accommodate electrical connections 174c. In some embodiments, circuit board 171 is directly electrically connected to image sensor 172 by electrical connections 174 while circuit board 171 and image sensor 172 are both directly attached to, and structurally supported by, first optical element 181.

First optical element 181 may have a uniform material composition. For example, first optical element 181 may be made of a glass, polymer, or other material having desired optical and/or structural characteristics. The material may be uniform through the entire first optical element 181 (e.g., including portions of first optical element 181 in front of circuit board 171 and image sensor 172).

In other embodiments first optical element 181 may be made of one or more different materials. Referring to FIG. 4, first optical element 181 may include a first material 181c, such as a glass, polymer, or other material having desired optical characteristics at least partially at locations in front of image sensor 172, and may include a second material 181d different than first material 182c at least partially at locations in front of circuit board 171. The optical properties of first optical element 181 may be less critical at locations in front of circuit board 171 around a perimeter of first material 181c. First material 181c may thus be selected to facilitate desired optical properties at locations above image sensor 172, and second material 181d may be selected primarily for desired cost, structural, or other characteristics.

In some embodiments, second material 181d of first optical element 181 may function as a frame surrounding first material 181c. In this manner, although second material 181d is referred to as a component of first optical element 181, it need not have properties that are optically advantageous. Moreover, first material 181c and second material 181d need not abut each other around an entire periphery of first material 181c. Rather, first material 181c may connect to second material 181d via supports, such that there are air gaps between the two materials or the presence of other materials. In some embodiments, first material 181c and second material 181d have a uniform thickness (e.g., first material 181c and second material 181d have thickness that are uniform at the interface of first material 181c and second material 181d). In some embodiments, second material 181d may form a portion of frame 186 and having a thickness substantially greater than a thickness of first material 181c. Front faces 171a, 172a of circuit board 171 and image sensor 172 are coplanar and directly attached to first material 181c and second material 181d, respectively, of first optical element 181, while lens barrel 187 and second, third, and fourth optical elements 182, 183, 184 are mounted in front of first optical element 181.

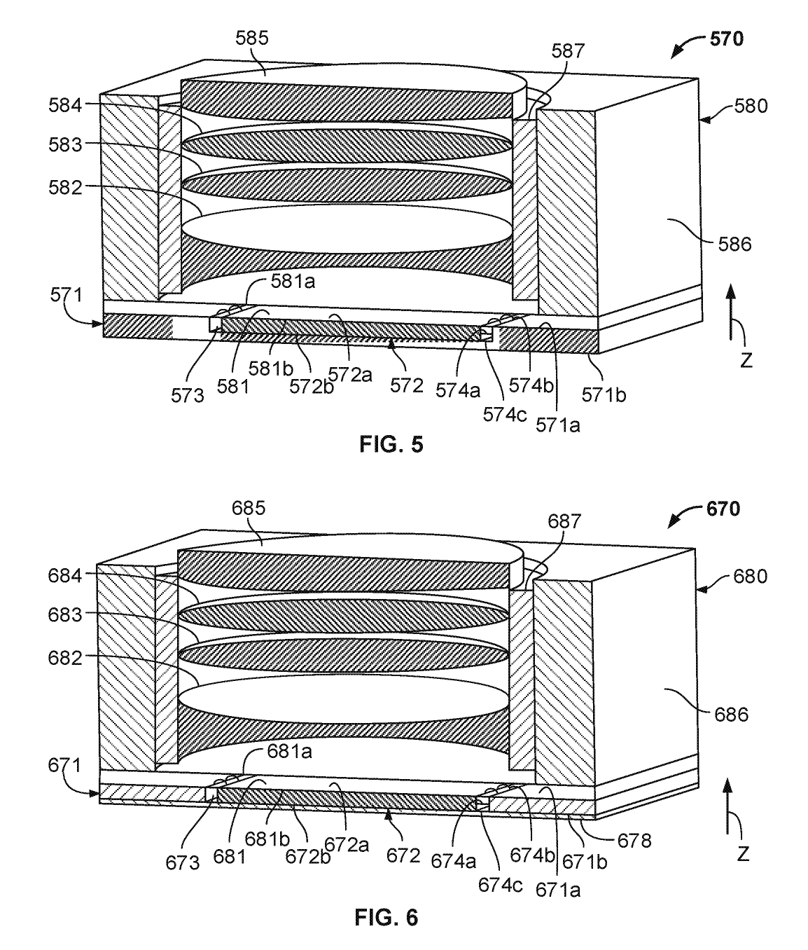

Referring to FIG. 5, a cross-sectional perspective view of another example camera module 570 is shown. Camera module 570 includes a circuit board 571 and image sensor 572 directly attached with first optical element 581, and, in some embodiments, may have features similar to camera module 170 described above. First optical element 581 provides optical characteristics that facilitate capture of high-quality images by image sensor 572 while also providing structural support to image sensor 572. Such a configuration can facilitate a compact overall size of camera module 570, particularly of a height of camera module 570 along the z-axis.

Circuit board 571 includes a region of reduced thickness in which image sensor 572 is accommodated. For example, circuit board 571 includes a cavity cut 573, and image sensor 572 is positioned within cavity cut 573. Image sensor 572 is electrically connected with circuit board via electrical connections 574 including wire bonds or other electrical connections that facilitate transmission of control signals and data. In some embodiments, electrical connections 574 include lateral wire bonds between adjacent sides of circuit board 571 and image sensor 572. Alternatively or additionally, electrical connections 574 may connect between rear face 572b of image sensor 572 and the cavity cut portion of circuit board 571, and/or may extend above front face 571a of circuit board 571 and front face 572a of image sensor 572.

Image sensor 572 includes a front face 572a aligned with a front face 571a of circuit board 571 in a coplanar arrangement. Front faces 571a and 572a are each directly attached to rear face 581b of first optical element 581 such that first optical element provides structural support of image sensor 572. First optical element 581 may thus facilitate capture of high-quality images by image sensor 572 while also providing structural support to image sensor 572. Front faces 571a, 572a, of circuit board 571 and image sensor 572 are each attached to a common optical element (e.g., rear face 581b of first optical element 581), and circuit board 571 is directly electrically connected to image sensor 572.

An image sensor 572 attached to first optical element 581 allows cavity cut 573 of circuit board 571 to be deeper such that a thickness of circuit board 571 below image sensor 572 may be relatively thin. In some embodiments, a thickness of circuit board 571 below image sensor 572 may provide a minimum thickness to carry image sensor 572, such as during manufacturing of camera assembly 570 and/or to facilitate electrical connection between circuit board 571 and image sensor 572. Accordingly, the overall thickness of camera module 570 may be reduced (e.g., as compared to some camera module configurations in which an image sensor is primarily supported by a circuit board or other support substrate attached to a rear face of image sensor).

Referring to FIG. 6, a cross-sectional perspective view of another example camera module 670 is shown. Camera module 670 includes a circuit board 671 and image sensor 672 directly attached with first optical element 681, and, in some embodiments, may have features similar to camera module 170 and 570 described above. First optical element 681 provides optical characteristics that facilitate capture of high-quality images by image sensor 672 while also providing structural support to image sensor 672. Such a configuration can facilitate a compact size of camera module 670, particularly of a height of camera module 670 along the z-axis.

Circuit board 671 includes a cavity cut through an entire thickness of circuit board 671 to define a space 673 that image sensor 672 is positioned within. A carrier 678 is attached to rear faces 671b, 672b of circuit board 671 and image sensor 672. Carrier 678 may facilitate manufacture of camera module 670 by supporting image sensor 672 and/or providing electrical connection between circuit board 671 and image sensor 672.

Image sensor 672 is electrically connected with circuit board via electrical connections 674 including wire bonds or other electrical connections that facilitate transmission of control signals and data. In some embodiments, electrical connections 674 include lateral wire bonds between adjacent sides of circuit board 671 and image sensor 672. Alternatively or additionally, electrical connections 674 may connect between rear face 672b of image sensor 672 and carrier 678, and carrier 678 may in turn be electrically connected with circuit board 671.

Front face of image sensor 672 is aligned with front face 671a of circuit board 671 in a coplanar arrangement. Front faces 671a and 672a are each directly attached to rear face 681b of first optical element 681. First optical element 681 may this facilitate capture of high-quality images by image sensor 672 while also providing structural support to image sensor 672. Front faces 671a, 672a, of circuit board 671 and image sensor 672 are thus each directly attached to a common optical element (e.g., rear face 681b of first optical element 681).

An image sensor 672 attached to first optical element 681 allows carrier 678 to be relatively thin. In some embodiments, the thickness of carrier 678 below image sensor 672 is less than the thickness of circuit board 671 and image sensor 672, and may have a minimum thickness required to carry image sensor 672 during manufacturing of camera module 670, and/or to facilitate electrical connection between circuit board 671 and image sensor 672. For example, carrier 678 may provide a temporary carrier that may be removed in a subsequent manufacturing step (e.g. after image sensor 672 is supported by first optical element 681). Alternatively or additionally, carrier 678 may protect image sensor 672 and its electrical connections with circuit board 671, during manufacturer and/or after installation within electronic device 670. Accordingly, the overall thickness of camera module 670 may be reduced (e.g., as compared to some camera module configurations in which an image sensor is primarily supported by a circuit board or other support substrate attached to a rear face of the image sensor).

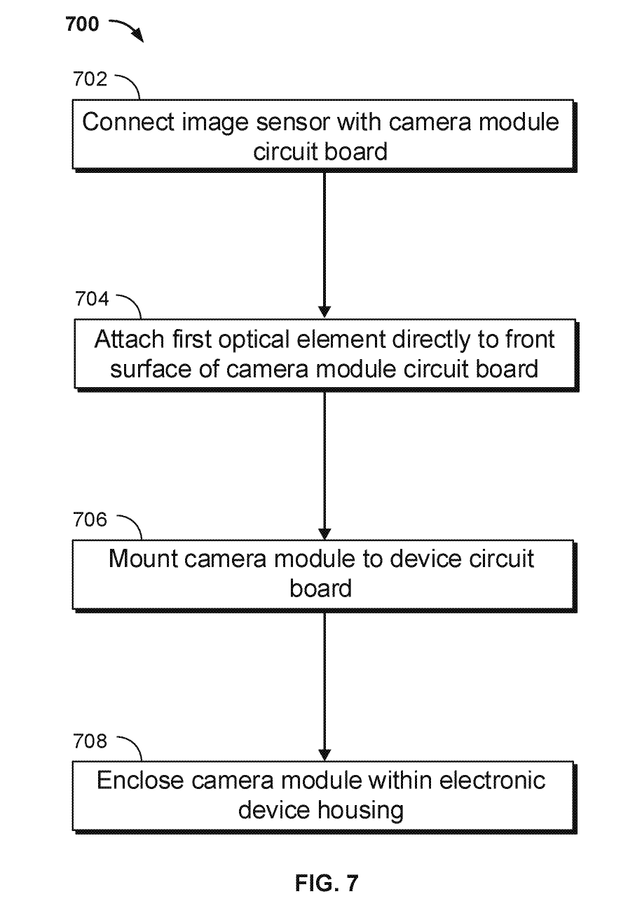

Referring to FIG. 7, a flow diagram of an example method 700 of manufacturing a camera module is shown. In some embodiments, method 700 includes operation 702 of electrically connecting an image sensor to a circuit board. The image sensor and circuit board may be electrically connected by wire-bonding the image sensor to the circuit board. In some embodiments, the image sensor is supported on a carrier substrate positioned below a rear face of the image sensor. The carrier substrate facilitates manipulation and positioning of the image sensor while the image sensor is electrically connected with the circuit board. In some embodiments, the carrier substrate is removable in a subsequent manufacturing step. Alternatively, carrier substrate may be present in the fully assembled camera module. For example, carrier substrate may provide a protective layer that protects rear faces of the image sensor and circuit board.

Method 700 further includes operation 704 of attaching a first optical element directly to a front surface of the circuit board and a front surface of the image sensor such that the circuit board and image sensor are both connected to a common optical element. The circuit board and/or image sensor may be bonded to the optical element by adhesive, such as an optically transparent adhesive, welds, or otherwise attached while allowing light to be transmitted to the image sensor through the optical element without excessive distortion. Additional components of a lens assembly, including a second, third, and fourth optical elements, lens barrel, and/or a camera module may be attached to the first optical element (e.g., in front of a front face of the first optical element) when the first optical element is attached to the circuit board or the image sensor. In other embodiments, one or more other additional components may be attached with the first optical element after the first optical element is attached to the circuit board or the image sensor.

Method 700 further includes operation 706 of mounting the camera module to a circuit board within a housing of an electronic device. In some embodiments, the camera module is mounted to a circuit board and positioned in alignment with an aperture through the electronic device housing. For example, the camera module may be electrically connected with the circuit board and positioned in alignment with an aperture through a front cover of the electronic device such that the camera module is configured as a front-facing camera. In other embodiments, camera module may be positioned in alignment with an aperture through a rear cover of the electronic device (e.g., on an opposite side of the electronic device from a main user display) such that the camera module is configured as a rear-facing camera.

Method 700 may further include operation 708 of mounting other electronic components within the housing of the electronic device and enclosing the housing to complete the electronic device. For example, an outer cover may be engaged with portions of the housing to enclose the camera module within the electronic device. In some embodiments, rear faces of the circuit board and image sensor electrically connected to the circuit board are not directly attached to a support substrate.

While this specification contains many specific implementation details, these should not be construed as limitations on the scope of any disclosed technology or of what may be claimed, but rather as descriptions of features that may be specific to particular embodiments of particular disclosed technologies. Certain features that are described in this specification in the context of separate embodiments can also be implemented in combination in a single embodiment in part or in whole. Conversely, various features that are described in the context of a single embodiment can also be implemented in multiple embodiments separately or in any suitable subcombination. Moreover, although features may be described herein as acting in certain combinations and/or initially claimed as such, one or more features from a claimed combination can in some cases be excised from the combination, and the claimed combination may be directed to a subcombination or variation of a subcombination. Similarly, while operations may be described in a particular order, this should not be understood as requiring that such operations be performed in the particular order or in sequential order, or that all operations be performed, to achieve desirable results. Particular embodiments of the subject matter have been described. Other embodiments are within the scope of the following claims.

1. A camera module, comprising:
a circuit board having a front face and a rear face;
an image sensor having a front face and a rear face, the image sensor electrically connected to the circuit board; and
a first optical element arranged in front of the front face of the image sensor and the front face of the circuit board, wherein the front face of the circuit board and the front face of the image sensor are each directly attached to the first optical element;
wherein the rear face of the circuit board and the rear face of the image sensor are not directly attached to a common support substrate.

2. The camera module of claim 1, wherein the image sensor is nested in an opening of the circuit board.

3. The camera module of claim 1, wherein an entire perimeter of the image sensor is surrounded by the circuit board.

4. The camera module of claim 1, wherein the image sensor is electrically connected to the circuit board by wire leads extending between the image sensor and the circuit board.

5. A camera module, comprising:
a circuit board having a front face and a rear face;
an image sensor having a front face and a rear face, the image sensor electrically connected to the circuit board; and
a first optical element arranged in front of the front face of the image sensor and the front face of the circuit board, wherein the front face of the circuit board and the front face of the image sensor are each directly attached to the first optical element;
wherein the image sensor is attached to the first optical element over the entire front face of the image sensor.

6. The camera module of claim 1, wherein the first optical element has a concave shape and the image sensor is attached to the first optical element around a perimeter of the concave shape.

7. The camera module of claim 1, wherein the first optical element includes a central lens portion made from a first material and a surrounding frame portion made from a second material.

8. The camera module of claim 7, wherein the front face of the circuit board is attached to the surrounding frame portion and the front face of the image sensor is attached to the central lens portion.

9. The camera module of claim 1, further comprising an electronic device having a front cover and a display visible through the front cover.

10. The camera module of claim 9, wherein the image sensor is arranged to receive light through an aperture of the front cover.

11. The camera module of claim 10, further comprising an electronic device housing including a rear surface opposite the front cover, wherein the image sensor is arranged to receive light through the rear surface of the electronic device housing.

12. The camera module of claim 1, further comprising second, third and fourth optical elements, the second, third and fourth optical elements arranged in a lens barrel.

13. The camera module of claim 12, further comprising a voice coil motor, at least one of the second, third, or fourth optical elements movable by the voice coil motor.

14. An electronic device, comprising:
a circuit board having a front face and a rear face;
an image sensor having a front face and a rear face, the image sensor nested in an opening of the circuit board and electrically connected to the circuit board;
a first optical element arranged in front of the front faces of the image sensor and the circuit board;
a user interface display; and
a housing having an aperture, wherein the front face of the circuit board and the front face of the image sensor are directly attached to the first optical element, the image sensor arranged in alignment with the aperture of the housing, and wherein the rear face of the circuit board and the rear face of the image sensor are not directly attached to a common support substrate.

15. The camera module of claim 14, wherein the image sensor is directly attached to the first optical element over the entire front face of the image sensor.

16. The camera module of claim 14, wherein the first optical element includes a central lens portion made from a first material and a surrounding frame portion made from a second material.

17. The camera module of claim 14, further comprising second, third and fourth optical elements, the second, third and fourth optical elements arranged in a lens barrel.

18. The camera module of claim 17, further comprising a voice coil motor, at least one of the second, third, or fourth optical elements movable by the voice coil motor relative to the first optical element and the image sensor.

19. A method of manufacturing a camera module, comprising:
electrically connecting an image sensor with a circuit board;
attaching a first optical element directly to a front face of an image sensor and a front face of the circuit board;
enclosing the circuit board, image sensor, and first optical element within a housing of an electronic device without directly attaching a rear face of the circuit board and a rear face of the image sensor to a common support substrate.

20. The method of claim 19, wherein the step of attaching a first optical element comprises directly attaching the first optical element to the entire front face of the image sensor.

21. The camera module of claim 1, wherein the rear face of the image sensor is not directly attached to a support substrate.

22. The camera module of claim 4, wherein the wire leads are entirely to a rear of the rear face of the first optical element and to the rear of the front face of the image sensor.

23. The camera module of claim 1, comprising a second optical element arranged within a camera module frame, the camera module frame mounted entirely in front of the first optical element.
